(19) United States
(12) Patent Application Publication
(10) Pub. No.: US 2026/0029828 A1
(43) Pub. Date: Jan. 29, 2026

(54) MODULAR EXTENSION ASSEMBLY FOR ENLARGING AN INFORMATION PROCESSING SYSTEM

(71) Applicant: HEWLETT PACKARD ENTERPRISE DEVELOPMENT LP, Spring, TX (US)

(72) Inventors: Anil Yuksel, Houston, TX (US); Steven Michael Novack, Houston, TX (US); Pranay Mahendra, Tomball, TX (US); John R. Grady, Cypress, TX (US)

(21) Appl. No.: 18/930,409

(22) Filed: Oct. 29, 2024

Related U.S. Application Data
(60) Provisional application No. 63/676,720, filed on Jul. 29, 2024.

(51) Int. Cl. G06F 1/20; H05K 7/20

(52) U.S. Cl. CPC G06F 1/20; H05K 7/20145; H05K 7/20727; H05K 7/20772

(57) ABSTRACT

A modular extension assembly can be used to expand the size of an information processing system, which may improve thermal performance. The modular extension assembly may include an extension chassis which is mounted to the top of the system chassis of the system, thereby expanding a height and volume of the overall system. The assembly may also include a fan extension zone comprising an opening arranged to receive fans protruding from the system chassis into the extension chassis. The assembly also includes extension module zones in the extension chassis and extension modules are removably installed in the extension modules zones. Each extension module comprises a module tray and one or more airflow guides to guide airflow through the assembly. Different extension modules can be selected depending on the desired configuration of the system.

### CROSS REFERENCE TO RELATED APPLICATION

This application claims priority to U.S. Provisional Application No. 63/676,720, filed 29 Jul. 2024, which is incorporated by reference herein in its entirety.

### INTRODUCTION

Information processing devices, such as computers and networking devices, generate heat when in use, and cooling systems may be utilized to remove heat from components of the information processing devices to keep them within desired operating temperatures. These cooling systems generally comprise air cooling systems, liquid cooling systems, or a hybrid air/liquid cooling system. An air cooling system utilizes fans to draw cooling air into the system, flow the air through the system, with the air impinging upon system components and/or heatsinks attached to the components to remove heat therefrom, and then exhaust the heated from the system. A liquid cooling system has a liquid cooling loop through which cooling liquid is pumped, with the liquid coolant being thermally coupled to system components via cold plates or similar devices. The heated liquid may be directed to a heat exchanger to cool the liquid coolant by heat exchange with another medium. Fans are also present in many liquid cooling systems, for example to flow air through a heat exchanger which cools the liquid coolant or to cool other components of the system which are not liquid cooled.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic diagram illustrating an example modular extension assembly.

FIGS. 2A and 2B are schematic diagrams illustrating an example modular extension system from which the modular extension assembly of FIG. 1 can be assembled.

FIG. 3 is a schematic diagram illustrating an example information processing system comprising the modular extension assembly of FIG. 1.

FIG. 4 is top-front perspective view of another example modular extension assembly.

FIG. 5 is bottom-side perspective view of the modular extension assembly of FIG. 4.

FIG. 6 is top-rear perspective view of the modular extension assembly of FIG. 4 with front extension module in an uninstalled state.

FIG. 7 is top-front perspective view of the modular extension assembly of FIG. 4 with a CPU extension module in an uninstalled state.

FIG. 8 is detail perspective view of a portion of the modular extension assembly of FIG. 4.

FIG. 9 is top-front perspective view of the modular extension assembly of FIG. 4 with rear extension module in an uninstalled state.

FIG. 10 is a perspective view of an example information processing device comprising the modular extension assembly of FIG. 4 and a system chassis in an uninstalled state.

FIG. 11 is a front perspective view of the information processing device of FIG. 10 with the modular extension assembly in an installed state on the system chassis

FIG. 12 is a rear perspective view of the information processing device of FIG. 10 with the modular extension assembly in the installed state on the system chassis.

FIG. 13 is top view of the information processing device of FIG. 10.

FIG. 14 is a perspective view comparing an example base information processing system with the example information processing system of FIG. 10 formed by adding the modular extension assembly to the base information processing system.

FIG. 15 is a perspective view of a closed loop liquid cooling system.

### DETAILED DESCRIPTION

Information processing systems come in a variety of sizes, such as 1U, 2U, 3U, 4U, etc. (where “U” is a standardized length called a “rack unit” and 1U, 2U, etc. refers to the height of the system in terms of a number of these rack units), and a variety of configurations, such as liquid cooled vs air cooled, or having different numbers and/or locations of drives or other components. Generally, the size of the system is determined by the chassis which the system is manufactured with. The chassis houses and supports the components of the system and forms the outer boundary thereof. The chassis of the system also determines, at least to some extent, the available configurations of the system, as only some configurations may be compatible with a given chassis. For example, a chassis which is designed for a closed loop liquid cooling system may have a space and supports configured to receive a radiator of the cooling system, whereas a different chassis which is designed for an exclusively air-cooled system may not have space or supports for such a radiator. While some limited reconfiguration of a system can be done by altering internal components of the chassis, some configurations may require entirely different chassis and thus it might not be possible to change certain configurations without replacing the chassis entirely.

However, in some circumstances it may be desired to change the size and/or configuration of an information processing system after it has been manufactured, particularly to enlarge the system. Some of the best-selling servers in the industry are 1U and 2U offerings. These servers house a lot of technology in a relatively small amount of space. However, maximizing the amount of technology in these servers increases the airflow impedance of these servers substantially. The higher the airflow impedance of a server, the more difficult it is to move air through the server for cooling purposes. To address the higher airflow impedances of these servers, higher powered cooling fans running near peak power utilization are required to adequately cool the servers. This not only increases the overall power utilization of the server, it also results in higher acoustic signatures for our servers which in some customer environments is not acceptable.

Thus, it may be desired to increase the size of a system (e.g., go from 1U to 2U in size) because this might allow for better thermal performance, decreased power consumption, and improved sound signatures. Thermal performance might improve because increasing the size of the system may: allow for more surface area on the front and rear panels which can be used for air intake and exhaust; reduce internal impedance to airflow; allow for larger fans to be used (larger fans being able to move more air at a given fan speed); and/or allow for larger or more numerous heatsinks to be used. In addition, power consumption and acoustics may be improved because the improved thermals mentioned above can allow the fans to be driven at lower speeds while still maintaining desired levels of cooling.

As another example, it may be desired to increase the size of a system in order to allow for a change in its configuration. For example, a system which was originally designed to be exclusively air cooled might be convertible to a liquid cooled configuration if the size of the system could be increased sufficiently to accommodate a radiator.

It may be wondered why a consumer does not simply purchase a larger system from the beginning, rather than seeking to change the size after its manufacture. One reason why a consumer may purchase a smaller system despite its drawbacks is that larger systems often cost more. Another reason may be that smaller systems may allow for a greater density of systems within a given space, and consumers may. Another reason may be that systems of different size classes do not merely differ from one another in size, but also often differ from one another in other ways such as which components and/or how many such components are included in the system, and therefor a customer who does not have a need for the type and/or number of components which are included in a larger system may opt for the smaller system which better aligns with their component needs. Regardless of the reason why the consumer opted for the smaller system in the first place, they may later desire to increase the size of the system, for example to take advantage of improved thermal efficiency and/or to allow for changes in configuration.

But such changes in size and/or configuration of a system after its manufacture might not be feasible in many cases. As noted above, generally the size and configuration of the system is determined by the chassis it has at manufacture. Thus, changing the size and/or configuration of a system may require replacing the entire chassis thereof with a new one. But this can be a very complicated and costly process and may have knock-on effects, such as other components of the system (such as a motherboard) also needing to be replaced. Accordingly, the change in size and/or configuration may require so extensive a reconstruction of the system as to often not be worth the cost and effort.

This disclosure addresses the issues discussed above by providing a modular extension assembly, which can be mounted onto an existing chassis of a system to increase the size (i.e., volume) of the system. A cover or lid of the chassis can be removed and the modular extension assembly can be mounted onto the walls of the chassis in lieu of the cover, in some cases using the same mounting features which were originally used to secure the cover to the walls. The modular extension assembly and the original chassis then together form a new extended chassis which is taller than the original chassis. Thus, all of the benefits noted above related to increasing the size of the system may be realized thanks to the addition of the modular extension assembly, particularly improved thermal efficiency, decreased power consumption, and decreased noise. Moreover, the original chassis is retained and the components mounted thereto do not need to be removed or changed, and therefore the increase in size of the system can be effectuated in a much simpler and less costly manner than replacing the original chassis with an entirely new one.

The modular extension assembly may also be configured to receive a number of extension modules. The extension modules may have a variety of different configurations, which will be described below, and may be placed in a variety of different locations within the extension assembly, called herein extension module zones. The extension modules may control and guide airflow through the modular extension assembly and/or through other parts of the system and may thus assist in improving thermal performance thereof. In other words, in addition to the thermal performance improvements which come simply from increasing the size of the system, additional thermal performance improvements may be achieved by the inclusion of the extension modules. There may be a variety of types of extension modules which may be designed for use in different positions in the assembly and which may also have different configurations relative to one another. In addition to having different thermal properties, some extension modules may also allow for different system configurations—for example, some extension modules may include therein system components (or structure designed to receive such components) so that adding the extension module also expands upon the capabilities of the system. There may be more types of extension modules available than are used in a given system at a single time, and thus different system configurations can be achieved based on which particular set of extension modules happens to be selected for inclusion in the modular extension assembly. In this manner, the modular extension assembly is configurable to achieve many desired system configuration, making it very versatile.

With each new generation of technology (e.g. processors, memory, storage devices, etc.), power requirements are rising at accelerating rates, making it challenging for customers to fully populate their server racks with servers and still have the necessary capacity to power all of the servers in the rack. In a significant number of cases, customers do not have the necessary power to completely fill their server racks with servers, leaving a quarter or more of the rack unpopulated. In addition, increasing power requirements of the internal server components are necessitating higher powered thermal solutions (e.g. high performance fans), driving the total power consumption of the server higher. The examples disclosed herein can address these challenges by allowing the customers to retrofit their servers to increase their size, thus utilizing the otherwise empty space being left in their server racks due, while also improve the thermal performance of the servers and helping reduce server power usage and noise.

Turning now to the figures, various devices, systems, and methods in accordance with nonlimiting aspects of the present disclosure will be described.

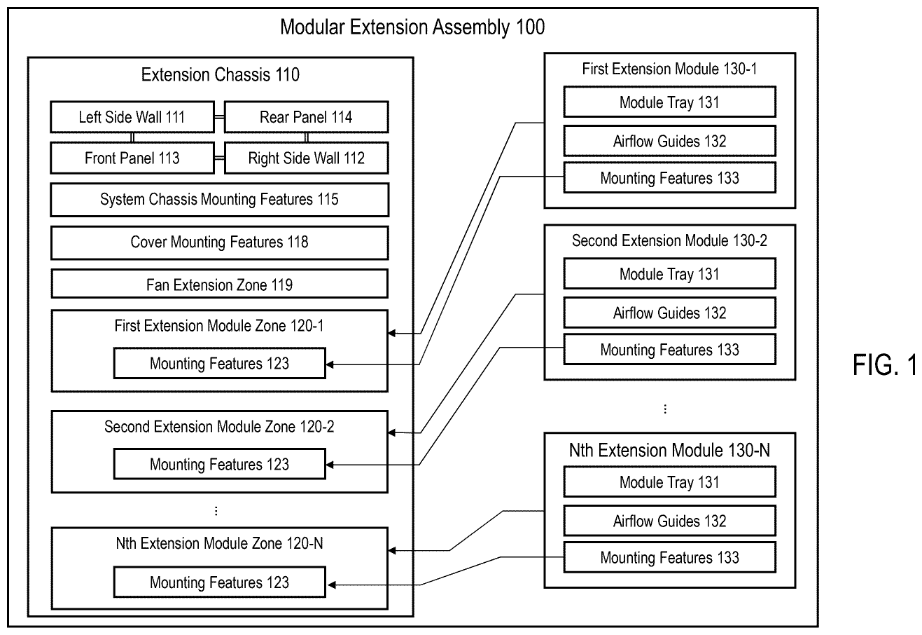

FIGS. 1-3 are schematic diagrams conceptually illustrating a modular extension assembly 100, a modular extension system 201, and an information processing system 302. FIGS. 1-3 are schematic in nature and are not intended to illustrate specific shapes, dimensions, positional relationships, or other structural details accurately or to scale, except to the extend unless otherwise noted below. It should be understood that implementations of the modular extension assembly 100, modular extension system 201, and an information processing system 302 can vary from one another in various aspects. Some implementations of the modular extension assembly 100, modular extension system 201, and/or information processing system 302 may have different numbers and arrangements of the illustrated components. Some implementations of the modular extension assembly 100, modular extension system 201, and information processing system 302 may include other parts that are not illustrated in FIGS. 1-3. Some implementations of the modular extension assembly 100, modular extension system 201, and/or information processing system 302 may omit one or more of the parts that are illustrated in FIGS. 1-3. In FIGS. 1-3, physical engagement between parts is indicated by solid lines, with double solid lines indicating attachment or more permanent connection and single lines indicating removable or temporary connections or other forms of engagement not resulting in attachment such as contact or one item being disposed within another.

As explained above, the modular extension assembly 100 is configured to be installed on a separately manufactured information processing system, post manufacture (e.g., during a field retrofit/upgrade) to expand the size thereof. Thus, the modular extension assembly 100 has dimensions and mounting features that are designed to be compatible with one or more particular systems. However, many information processing systems, including future systems yet to be designed, may have dimensions and mounting features compatible with the modular extension assembly 100. For ease of description, reference will be made to “the system” below when describing the modular extension assembly 100, and these references should be understood as referring to any one of the systems with which the modular extension assembly 100 is compatible and on which the modular extension assembly 100 is either installed or to be installed, as the case may be.

As shown in FIG. 1, the modular extension assembly 100 may comprise an extension chassis 110 which has a left side wall 111, right side wall 112, front panel 113, and rear panel 114. These may be connected together to form a box-like frame.

The extension chassis 110 also comprises system chassis mounting features 115 to facilitate mounting to the original chassis of the system on which the assembly 100 is to be installed. The extension chassis 110 also comprises cover mounting features 118 to allow the original cover of the system to be mounted to the extension chassis 110. These system chassis mounting features 115 and cover mounting features 118 may be formed in any of the walls/panels 112-114. In some examples, the system chassis mounting features 115 mimic the mounting features of a cover of the system so that the system chassis mounting features 115 can engage with the same mounting features of the system chassis with which the cover previously engaged prior to the assembly 100 being installed. Similarly, in some examples, the cover mounting features 118 mimic the mounting features of the system chassis of the system so that the cover mounting features 118 can engage with same mounting features of the cover which the system chassis previously engaged with. For example, in some systems the systems cover has mounting features comprising a number of protrusions from side walls thereof and the system chassis has a number of mounting features comprising slots into which the protrusions are to be received, thereby attaching the cover to the system chassis, and in some examples the system chassis mounting features 115 may also comprise protrusions that mimic the shape and locations of the cover's protrusions whereas the cover mounting features 118 may comprise slots mimicking the shape and locations of the slots of the system chassis.

The extension chassis 110 also comprises a fan extension zone 119. This is a space within the extension chassis 110 which is open to the interior of the original chassis below the extension chassis 110. This fan extension zone 119 may be configured to allow for fans of the system to extend from the original chassis into the extension chassis. This can allow for the original fans of the system to be replaced with larger fans, with a bottom portion of the new fans sitting in the original chassis and the top portion of the new fans sitting in the fan extension zone 119 of the extension chassis 110. In some cases, the fan extension zone 119 may be positioned so as to align with the place where the original fans were installed in the original chassis, so that the new fans can be installed in approximately the same location, as this may allow for existing fan connectors and/or mounting features to be used. The extension chassis 110 may also include fan mounting features in or adjacent the fan extension zone 119 which may be used to secure the new larger fans, in addition to or in lieu of fan mounting feature in the original chassis. This may allow, for example, seven 40 mm cooling fans in the 1U server to be replaced with six 60 mm cooling fans or five 80 mm cooling fans; or for six 60 mm cooling fans to be replaced with four 92 mm cooling fans or three 120 mm cooling fans; or any other desired change in fan size.

The extension chassis 110 also comprises a plurality of extension zones 120, with extension zones 120-1, 120-2, . . . , 120-N being illustrated in FIG. 1 as examples (N being any integer). Each extension zone 120 comprises a space within the interior of the extension chassis 110 which is configured to receive one of the extension modules 130. Each extension zone 120 also comprises mounting features 123 configured to engage with mounting features 133 of the corresponding extension module 130 to support and/or secure the module in the extension zone 120. Some or all of the mounting features 123/133 can include features which engage and support but without necessarily causing attachment—for example, the mounting features 123 may comprise a shelf or ledge and the mounting feature 133 may comprise a bottom surface of the module 130 which rests upon the shelf/ledge. Some or all of the mounting features 123/133 can alternatively include attachment features such as actuatable latches which engage to secure or lock the extension module 130 in place. (Attaching and non-attaching mounting features 123/133 can both be used together, in some examples).

As shown in FIG. 1, each extension module 130 is installed in one of the extension module zones 120. In FIG. 1, there are N extension modules 130-1 to 130-N to correspond to the N extension module zones 120-1 to 120-N, but it should be understood that N can be any integer. In other words, different implementations of the assembly 110 may have different numbers of extension module zones 120 and extension modules 130.

Each extension module 130 comprises a module tray 131 which forms a base or floor of the module 130. This module tray 131 may divide the interior space of the original chassis from the interior space of the extension module 130. Thus, in some examples, these two chassis spaces are substantially separated from one another by the module trays 131 except for in certain predetermined locations where apertures are deliberately added to connect the two spaces and/or in small gaps or seams between adjoining modules 130. An example of an aperture which may join the two interior chassis spaces is the aforementioned fan extension zone 119. Another example is a CPU cutout which may be provided in certain extension modules 130 to allow a CPU heatsink to extend from the interior of the original chassis into the interior of the extension chassis 110, as will be described below. One reason for separating the interior space of the original system chassis from the original space of the extension chassis 110 is to better control airflow through the system and prevent recirculation of air or bypassing of air away from desired regions to undesired regions. For example, in some cases, the airflow impedance through the bottom portion of the system in the original system chassis may be greater than the airflow impedance through the top portion of the system in the extension chassis 110, and therefore if the regions were not separated then it might be the case that less airflow than is desired may flow through certain portions of the original system chassis preferring instead to flow through the lesser impedance of the extension chassis 110, which might hurt rather than help thermal performance. However, because the module trays 231 substantially separate the interior of the extension chassis 110 from the interior of the original system chassis (except in certain predetermined locations), such bypassing may be prevented.

Each extension module 130 also may comprise one or more airflow guides 132, which are attached to the module tray 131 and configured to control and/or guide airflow through the extension module 130. These airflow guides 132 may include walls defining airflow channels, movable or fixed baffles or doors to block or redirect airflow, apertures to allow airflow to move from one location to another, such as from the extension module 130 down into the original of the original system chassis, or any other structure which is configured to control or guide airflow.

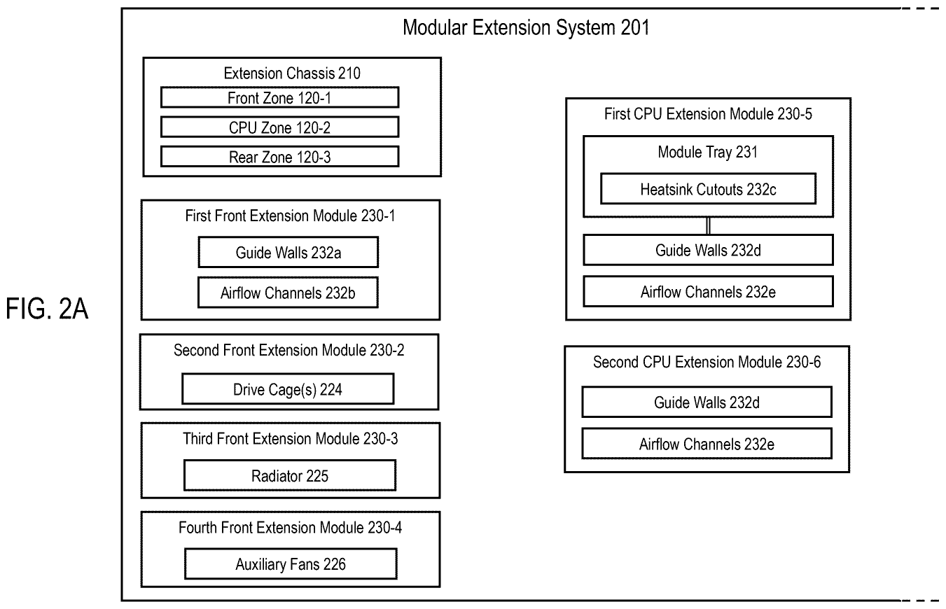

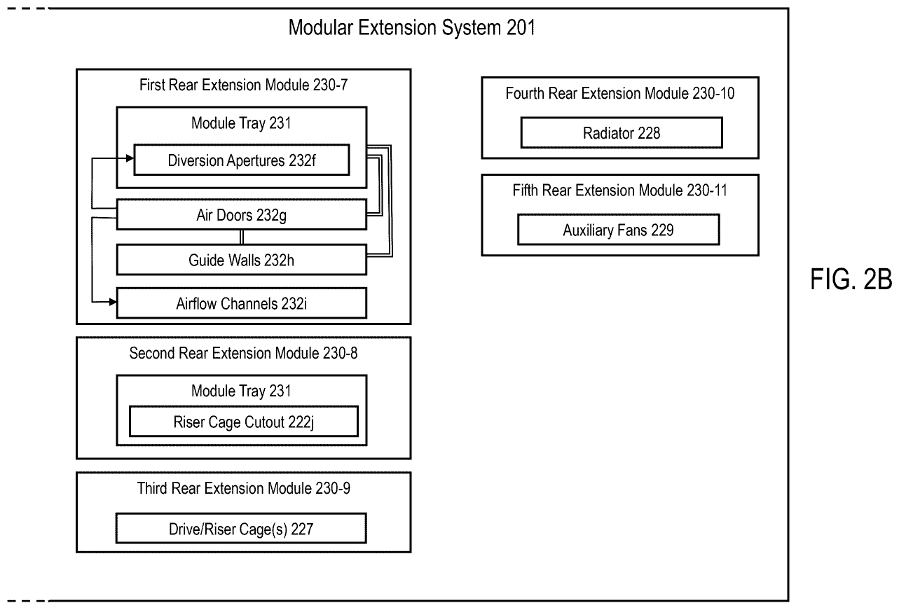

Some particular examples of the extension module 130 will be described in greater detail below with respect to the module extension system 201 of FIGS. 2A and 2B. The extension module system 201 may be used to create instances of the extension module assembly 100. In other words, the system 201 may be a kit or system of parts which can be selectively assembled in various combinations to create different implementation of the extension module assembly 100.

The extension module system 201 comprises an extension chassis 210, which is an implementation example of the extension chassis 110 of FIG. 1 (features of the extension chassis 210 are not shown in FIG. 2A for simplicity).

In the example of FIG. 2A-2B, it is assumed that the extension chassis 210 has three of the extension module zones 120, which include a front zone 120-1, a CPU zone 120-2, and a rear zone 120-3. The front extension module zone 120-1 is positioned forward of the fan extension zone 119 (not illustrated in FIG. 2A), the middle extension module zone 120-2 is positioned rearward of the fan extension zone 119 (e.g., over a CPU region of the original chassis), and the rear extension module zone 120-3 is positioned rearward of the middle extension module zone 120m.

The extension module system 201 also comprises a plurality of different types of extension modules 230. Each extension module 230 is a particular implementation example of, and can be used as one of, the extension modules 130 of FIG. 1. More specifically, a particular configuration or implementation of the assembly 100 can be created by selecting a corresponding subset of the extension modules 230 from FIGS. 2A and 2B and installing those in the chassis 210. Thus, FIGS. 2A and 2B are not intended to illustrate one particular implementation of the assembly 110, but rather they illustrate a system or “kit” from which multiple different implementations of assembly 110 could be selectively formed.

In some examples, the types of extension modules 230 may include: front extension modules 230-1 to 230-4, any one of which may be installed in the front extension module zone 120-1; CPU extension modules 230-5 to 230-6, any one of which may be installed in a CPU extension module zone 120-2 over the CPUs; and rear extension modules 230-7 to 230-11, any one of which may be installed in the rear extension module zone 120-3.

A first front extension module 230-1 may comprise guide walls 232a. These guide walls 232 may be coupled perpendicularly to the module tray of the module 230 (the module tray is not illustrated in FIG. 2A or 2B for some modules 230, but may be present in each module 230). The guide walls 232a may define airflow channels 232b between adjacent guide walls 232a which may extend parallel to the left and right walls of the extension chassis. These guide walls 232a and the airflow channels 232b defined therebetween are examples of the airflow guides 132 of FIG. 1, and may direct airflow through the module 230-1 while keeping the airflow moving on substantially straight paths with minimal lateral deviations or swirls, which can help improve airflow rates through the system.

A second front extension module 230-2 may comprise one or more drive cages 224 (or other pluggable module cages). These drive cages 224 may be mounted to, or form part of, the module tray of the module 230, and may allow for the capabilities of a system to be expanded by allowing for additional drives to be installed therein beyond the maximum that would have been available in the system prior to the addition of a modular extension assembly 100. The second front extension module 230-2 may also include any other guide structure 132 described herein.

A third front extension module 230-3 may comprise one or more radiators 225. A radiator is a liquid-to-air heat exchanger which may be used in a closed loop liquid cooling system. For example, a cold plate may be attached to a CPU in the interior of the original system chassis of a system, and then hoses/pips may connect that cold plate to the radiator disposed in the front extension module 230-3 of an assembly 100 mounted to the original system chassis. The third front extension module 230-3 may allow a system which was originally designed for air cooling to be retrofitted to add closed loop liquid cooling capabilities. In some cases, this might not be possible within the original chassis of the system, as there may be no room therein for the radiator which is used to remove heat from the liquid coolant. However, by adding the modular extension assembly 100 with the third front extension module 230-3 therein, space may be made for the radiator.

A fourth front extension module 230-4 may comprise one or more auxiliary fans 226. The auxiliary fans 226 may be added in addition to the fans which are already disposed in the original system chassis. These auxiliary fans 226 may provide additional airflow through the extension chassis 210 and/or the original system chassis, and may be used in addition to or in lieu of replacing the original fans with larger fans. In some examples, the auxiliary fans 226 of module 230-4 may be combined with the radiator 224 of module 230-3.

A first CPU extension module 230-5 may comprise guide walls 232d coupled perpendicularly to the module tray 231 and defining airflow channels 232e therebetween, similar to the guide walls 232a and airflow channels 232b described above. In addition, the first CPU extension module 230-5 may comprise heatsink cutouts 232c in the module tray 231. In some examples, each heatsink cutout 232c is formed in a corresponding one of the guide channels 232e. There may be one heatsink cutout 232c per CPU in the system, and the heatsink cutouts 232c may be positioned so as to align with (i.e., to be disposed over) the corresponding CPUs. The CPU cutouts 232c may allow the heatsinks of the CPUs to extend upward into the extension chassis 210. This may allow the original heatsinks to be replaced with larger heatsinks. For example, a 1U server may originally have heatsinks designed for 1U systems, but when the modular extension assembly 100 is attached thereto with the first CPU extension module 230-5 therein, these 1U heatsinks could be replaced with taller heatsinks that are designed for a 2U system, for example, with the top halves thereof extending through the CPU cutouts 232c.

A second CPU extension module 230-6 may comprise guide walls 232d coupled perpendicularly to the module tray 231 and defining airflow channels 232e therebetween, similar to the guide walls 232d and airflow channels 232e described above. However, unlike the first CPU extension module 230-5, the second CPU extension module 230-6 may lack heatsink cutouts 232c in the module tray 231. This module 230-5 may be used, for example, in a system which uses liquid cooling for the CPUs, as in such cases heatsinks may not be needed and therefore heatsink cutouts 232c may not be needed.

A first rear extension module 230-7 may comprise guide walls 232h coupled perpendicularly to the module tray 231 and defining airflow channels 232i therebetween, similar to the guide walls 232a and airflow channels 232b described above. In addition, the first rear extension module 230-7 may comprise air doors 232g and diversion apertures 232f. The diversion apertures 232f comprise apertures through the module tray 231, which connect the airflow channels 232i to the space below the module tray 231, i.e., the interior space of the original system chassis. In some examples, there are sets of the diversion apertures 232f, with each set being disposed in a corresponding one of the airflow channels 232i. Each airflow door 232g is disposed adjacent to a corresponding set of the diversion apertures 232f. The airflow doors 232g are movable between two configurations—a first configuration in which they block airflow through the corresponding set of diversion apertures 232f while allowing airflow through the corresponding airflow channel 232i, and a second configuration in which they block airflow through the corresponding airflow channel 232i while allowing airflow through the corresponding set of diversion aperture s 232f. Thus, first rear extension module 230-7 can provide for variable airflow patterns by adjusting the doors 232g as needed. For example, a door 232g may be placed in the second configuration to provide additional cool air to components located in the rear of the system chassis by diverting some of the air from the assembly 100 into the system chassis. Or a door 232g may be placed in the first configuration to exhaust heated air from the system. For example, in some implementations, the doors 232g disposed in channels 232i which are aligned with CPU heatsinks may be put in the second configuration because those channels 232i carry air that has been heated by the CPU heatsinks, whereases doors which are disposed in channels 232i which are not aligned with CPU heatsinks may be put in the first configuration because those channels 232i carry cool air which has not been heated by the CPU heatsinks. In some examples, some or all of the doors 232g are not movable between configurations, but instead are fixed in place. For example, some doors 232g may be fixed in the first configuration while others are fixed in the second configuration. In some examples, the diversion apertures 232f and/or air doors 232g may be omitted.

A second rear extension module 230-8 may comprise a riser cage cutout 222j in the module tray 231 thereof. This riser cage cutout 222j may allow for a larger riser cage to be installed in the system than would otherwise be possible, with part of the riser cage sitting within the original system chassis and part extending up into the extension chassis 210 via the riser cage cutout 222j. This may facilitate, for example, the installation of a large GPU or other large expansion card which might not have fit in the original system.

A third rear extension module 230-9 may comprise a driver/riser cage 227. Unlike the second rear extension module 230-8, in the third rear extension module 230-9 the drive/riser cage 227 does not necessarily extend into both the original system chassis and the extension chassis 210, but instead is an addition drive cage or riser cage 227 which is added in the module 230-9 in addition to any other drive/riser cages which are in the system chassis.

A fourth rear extension module 230-10 may comprise radiator 228. The radiator 228 may allow for liquid cooling to be provided to a system, similar to the radiator 225 described above. In particular, in some examples, the third front extension module 230-3 and the fourth rear extension module 230-10 may both be provided together to allow for two radiators to be installed in the same system.

A fifth rear extension module 230-11 may comprise one or more auxiliary fans 229. The auxiliary fans 229 may be added in addition to the fans which are already disposed in the original system chassis, similar to the auxiliary fans 226 already described above.

Although various different features are described above in relation to certain modules 230, it should be understood that these features could be combined together in other example modules not specifically illustrated herein. In particular, any combination or permutation of the above-described features may be combined together in various example modules 230 disclosed herein.

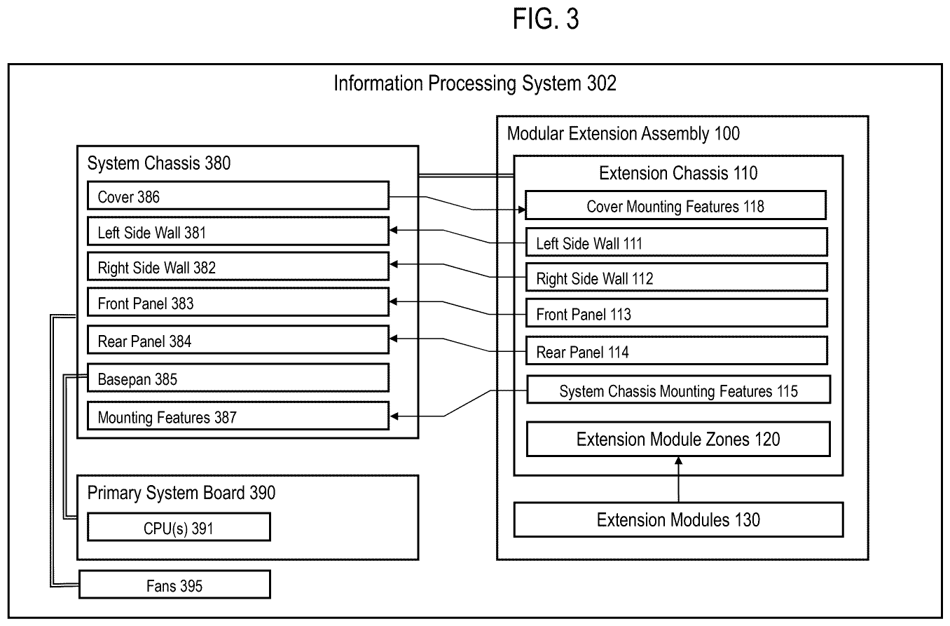

Turning to FIG. 3, an example information processing system 302 will be described. The system 302 may be a server, networking device, or other information processing device. The system 302 comprises a system chassis 380, a primary system board 390 housed in and supported by the system chassis 380, the modular extension assembly 100 mounted to the system chassis 380, and fans 395 secured to either or both of the system chassis 380 and the assembly 100. The primary system board 390 comprises one or more CPUs 391 mounted thereto. Additional computing components, such as storage drives, memory, expansion cards, and the like may also be included in system 302, as would be familiar to those of ordinary skill in the art.

The system chassis 380 comprises a left side wall 381, a right side wall 382, a front panel 383, a rear panel 384, a basepan 385, and a cover 386, which are all connected together to form a box-like structure. The cover 386 may be removable from the rest to allow access to an interior of the system chassis 380. The front panel 383 may include drive bays or other pluggable module bays in which modules may be removably inserted, as well as other apertures to allow airflow. The rear panel 384 may also include various pluggable module bays, apertures to allow airflow, electrical connectors, and the like.

The system chassis 380 also comprises mounting features 387 which are configured to engage interchangeable with either the system chassis mounting features 115 of the assembly 100 to mount the assembly 100 to system chassis 380, or which mounting features of the cover 386 to mount the cover to the system chassis 380 (in the absent of the modular extension assembly 100). In some examples, some (or all) of the mounting features 387 are formed in the left and right side walls 381 and 382. In some examples, some (or all) of the mounting features are also formed in front panel 383 and/or rear panel 384.

In some example, at least a subset of the mounting features 387 are the same mounting features which are used to mount the cover 386 to the rest of the chassis 380. Thus, in these examples, at least some of the system chassis mounting feature 115 of the assembly 100 may mimic mounting features of the cover 386 so as to allow them to mate with the mounting features 387. These example may beneficially allow the assembly 100 to be added to an existing system without the system needing to have been specially designed to receive the assembly 100. In some examples, mounting features 387 include slots configured to receive protrusions, which are part of the cover 386 or which are part of the system chassis mounting features 115 of the assembly 100.

The modular extension assembly 100 is an implementation of the assembly 100 of FIG. 1. In this example, the assembly 100 is mounted to the system chassis 380 with the extension chassis 110 being coupled thereto. Specifically, the left side wall 111 engages with and extends vertically from the left side wall 381, the right side will 112 engages with and extends vertically from the right side wall 382, the front panel 113 engages with and extends vertically from the front panel 383, and the rear panel 114 engages with and extends vertically from the rear panel 384. Together, the extension chassis 110 and the system chassis 380 for a combined chassis which has dimensions that exceed those of the original system chassis 380, so that the addition of the assembly 110 to the system chassis 380 has expanded the size (volume) of the system.

In this example, the same cover 386 which was designed to be part of the system chassis 380 may be mounted to the extension chassis 110 on top of the walls/panels 111, 112, 113, and 114. In particular, mounting features of the cover 386 may engage with the cover mounting features 118 of extension chassis 110. The cover mounting feature 118 may be part of any or all of the walls/panels 111, 112, 113, and 114. The cover mounting features 118 may mimic the mounting features 387 of the system chassis 380 so as to allow the cover 386 to mate therewith.

In the system 302, one or more extension modules 130 are installed in the extension module zones 120, as described above.

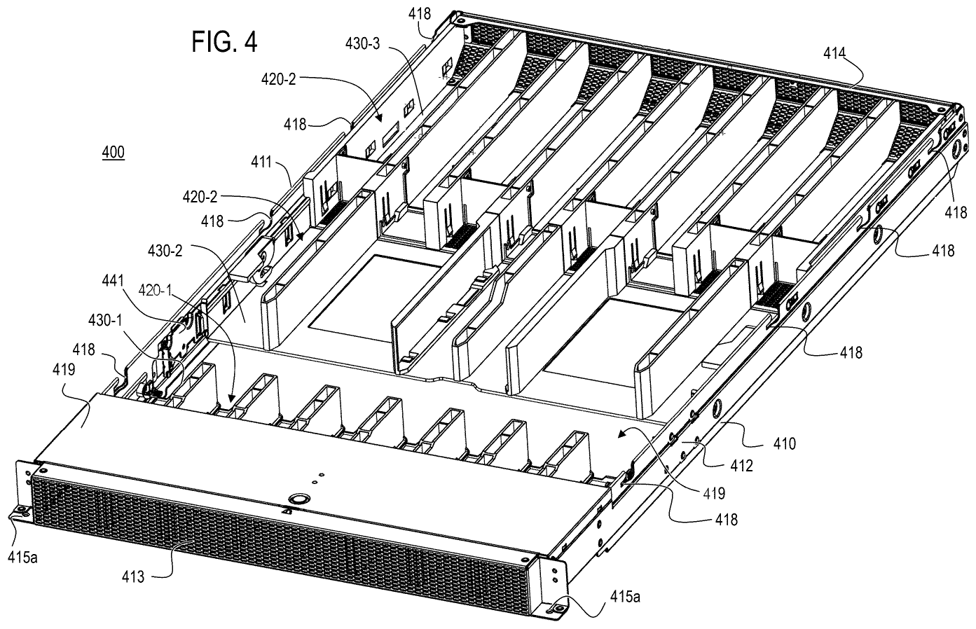

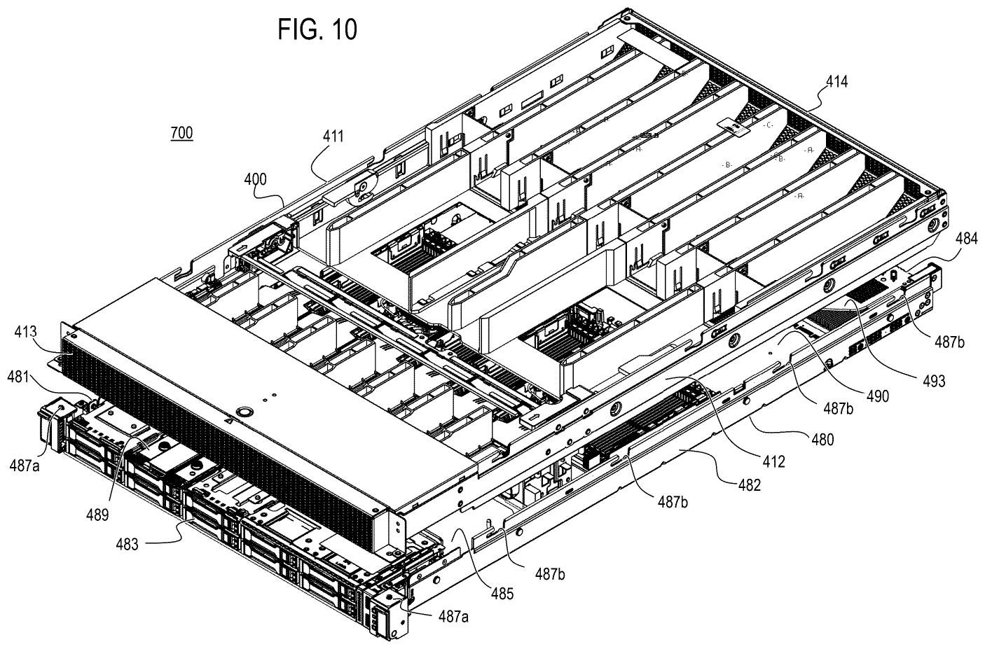

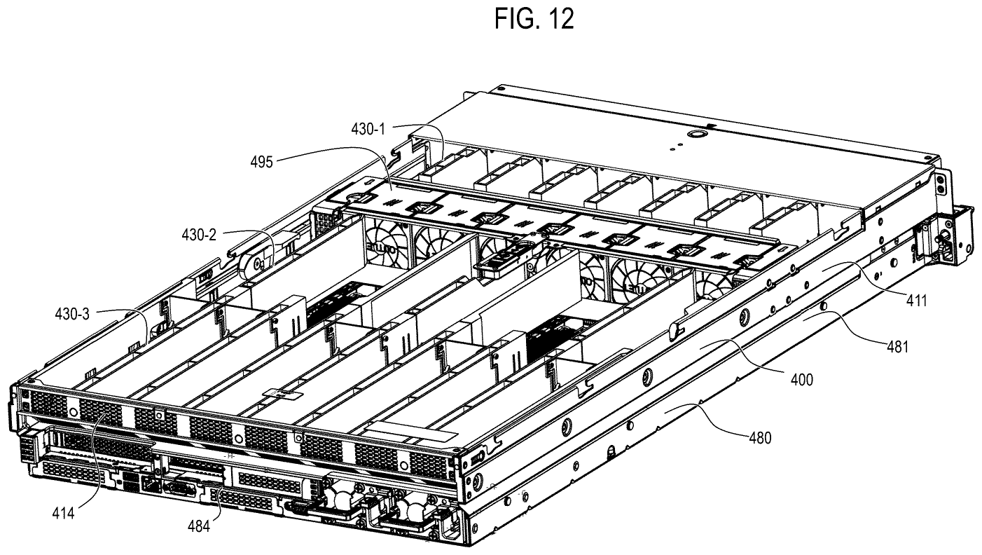

Turning to FIGS. 4-14, a modular extension assembly 400 and a system 702 comprising the same are shown. FIGS. 4-9 show the assembly 400 by itself in various states. FIGS. 10-14 shows the system 702 with the assembly 400 in various states. The assembly 400 is one implementation example of the assembly 100, and the system 702 is one implementation example of the system 302. Accordingly, assembly 400 and system 702 comprises various features which are implementation examples of corresponding features described above in relation to FIGS. 1-3, with the features of assembly 400 and system 702 having the same last two digits as the corresponding features of FIGS. 1-3, such as 430 and 130. The description above of the features in FIGS. 1-3 are thus applicable to the corresponding features shown in FIGS. 4-14, and duplicative description of aspects already described above may be omitted. In addition, the features of the assembly 400 and system 702 have the specific structures as shown in the figures, which represent one example way in which the corresponding feature of the assembly 400 and system 302 of FIGS. 1-3 can be structurally implemented. However, the assembly 400 and system 302 of FIGS. 1-3 are not limited to the specific structural details of the assembly 400 and system 702.

Note that for certain features there may be multiple instances of the feature, but in some cases a reference number is provided in the figures only in relation to one or some of the features. A person of ordinary skill in the art would be able to understand, based on the similarity in appearance, structure, and/or functionality, that these features represent different instances of the same type of feature notwithstanding some of the features not being labeled. Note that certain features may be identified by a reference number in only some of the figures in which they are visible, but a person of ordinary skill in the art would be able to understand that the same features are present in multiple views notwithstanding those features having a label in one figure and no label in another figure

As shown in FIG. 4, the modular extension assembly 400 comprises an extension chassis 410 which has a left side wall 411, right side wall 412, front panel 413, and rear panel 414. These may be connected together to form a box-like frame.

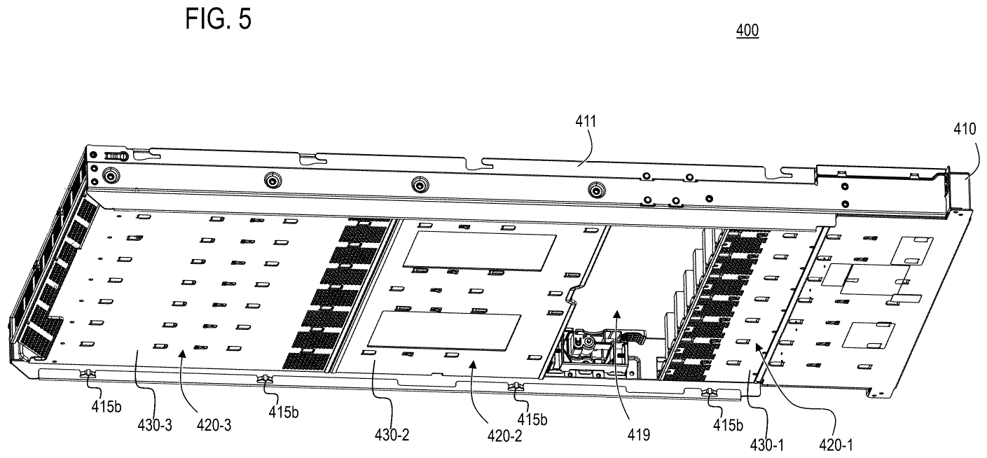

The extension chassis 410 also comprises system chassis mounting features 415 configured to engage with the mounting features 487 of the system chassis 480 of the system 702 on which the assembly 400 is to be installed. The mounting features 415 include two mounting features 415a in the form of screw holes which may be fastened to mounting features 487a on a front panel 483 portion of a system chassis 480 via screws, as shown in FIG. 10. The system chassis mounting features 415 also include mounting features 415b which are positioned on the interior bottom side of the left and right side walls 411 and 412, as shown in FIG. 5 (only the mounting features on the right side wall 412 are visible in FIG. 5, but similar mounting features may be disposed on the left side wall 411). These mounting features 415b comprise protrusions configured to engage with the slot shaped mounting features 487b in the side walls 481 and 482 of system chassis 480, as shown in FIG. 10 (only the mounting features 487b in the right side wall 482 are visible, but similar mounting features may be disposed on the left side wall 481).

The extension chassis 410 also comprises cover mounting features 418 to allow the original cover of the system to be mounted to the extension chassis 410. These cover mounting features 418 are formed in the side walls 411 and 412, as show in FIG. 4. The cover mounting features 418 mimic the mounting features 487b of the system chassis 480.

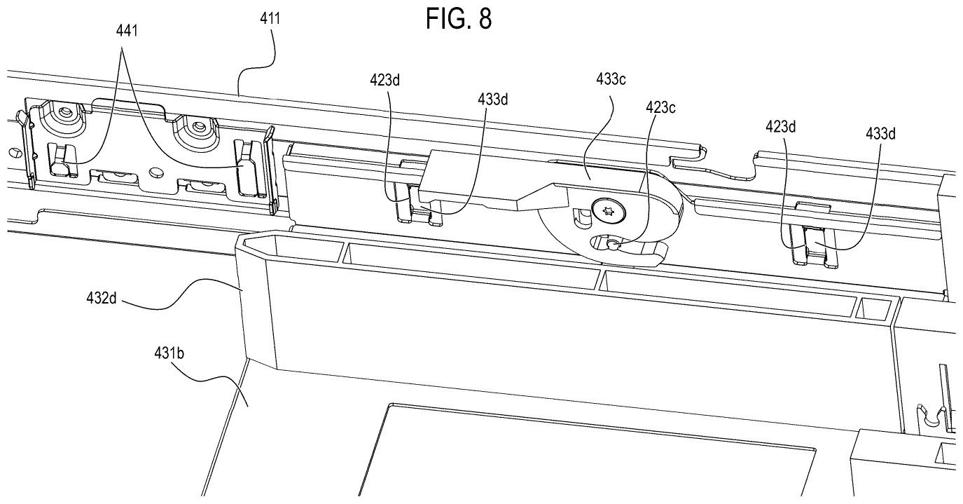

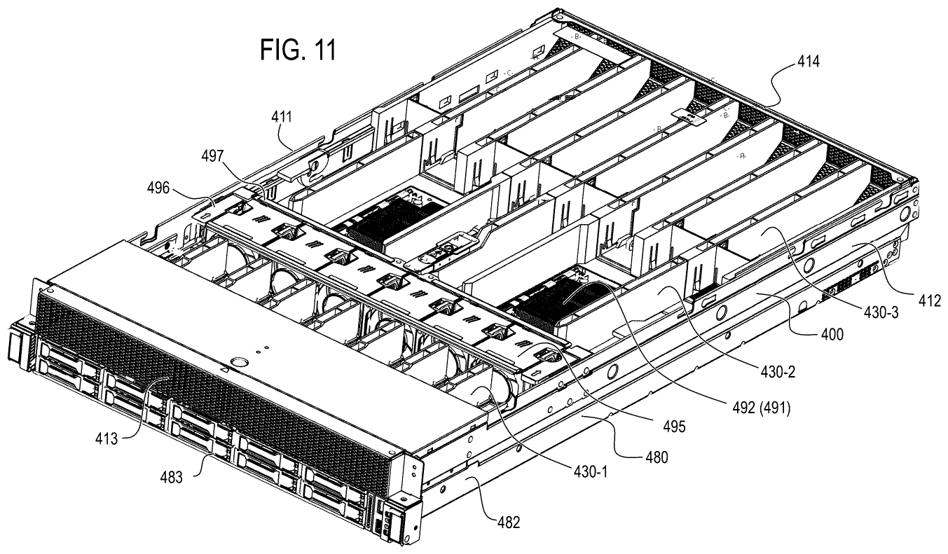

The extension chassis 410 also comprises a fan extension zone 419, as shown in FIG. 4. This is a space within the extension chassis 410 which is open to the interior of the original chassis 480 below the extension chassis 410. This fan extension zone 419 may be configured to allow for fans 495 of the system 702 to extend from the original chassis 480 into the extension chassis 410, as shown in FIGS. 11-13. This can allow for the original fans of the system to be replaced with larger fans, such as fans 495 shown in FIGS. 11-13, with a bottom portion of the new fans 495 sitting in the original chassis and the top portion of the new fans 495 sitting in the fan extension zone 419 of the extension chassis 410. In some cases, the fan extension zone 419 may be positioned so as to align with the place where the original fans were installed in the original chassis 480, so that the new fans 495 can be installed in approximately the same location, as this may allow for existing fan connectors and/or mounting features to be used. The extension chassis 410 may also include fan mounting features 441 in or adjacent the fan extension zone 419 (see FIGS. 4 and 8) which may be used to secure the new larger fans 495, in addition to or in lieu of fan mounting feature in the original chassis 480. For example, as shown in FIG. 11, fan mounting features 496 at the top side of a fan cage 497 may engage with the fan mounting features 441 of the assembly 440. This may allow, for example, seven 40 mm cooling fans in the 4U server to be replaced with six 60 mm cooling fans or five 80 mm cooling fans; or for six 60 mm cooling fans to be replaced with four 92 mm cooling fans or three 420 mm cooling fans; or any other desired change in fan size.

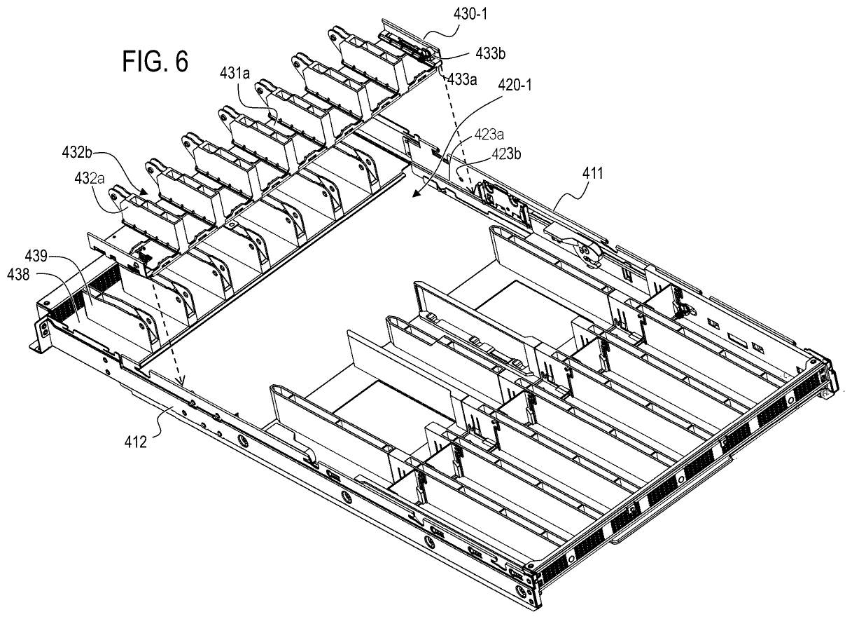

As shown in FIGS. 4, 5, and 13 in this example, the assembly 400 comprises three extension module zones 420-1 to 420-3 and three extension modules 430-1 to 430-3 installed therein, respectively. These extension modules 430-1 to 430-3 are shown in uninstalled states in FIGS. 6-9, and will be described in greater detail turn below.

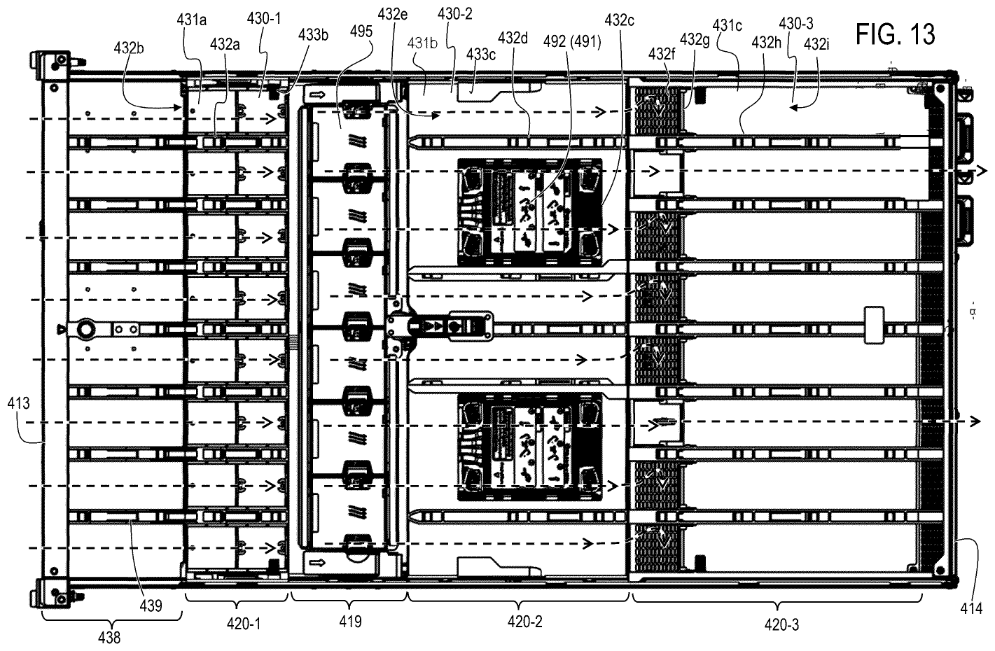

Extension module 430-1 is an example of the first front extension module 230-1 and is installed in the front module zone 420-1, as shown in FIG. 4. As shown in FIG. 6, the extension module 430-1 includes a tray 431a and multiple guide walls 432a (only one is labeled) coupled perpendicularly to the module tray 431a and disposed parallel to the left and right side walls 411 and 412. The guide walls 432a may define airflow channels 432b (only one labeled) between adjacent guide walls 432a. The airflow channels 432b extend parallel to the left and right walls 411 and 4122 of the extension chassis 410. These guide walls 432a and the airflow channels 432b defined therebetween may direct airflow through the module 430-1 while keeping the airflow moving on substantially straight paths with minimal lateral deviations or swirls, which can help improve airflow rates through the system. They also prevent air from bypassing down into the lower portion of chassis 480. For example, FIG. 13 illustrates some airflow paths through the assembly 400 with dash-lined arrows.

As shown in FIG. 6, front module extension zone 420-1 and extension module 430-1 comprise mounting features 423a, 423b and 433a, 433b, respectively, which engage one another to mount the extension module 430-1 to the front module extension zone 420-1. The mounting features 423a are ledges formed in the side walls 411 and 412, and the mounting features 433a comprise bottom edges of the tray 431, which rests on the ledges of mounting features 423a to support the module 430-1. The mounting features 423b comprise apertures through the side walls 411 and 412 and the mounting features 433b comprise latches which include a post or screw which, when actuated, protrudes through the apertures of mounting features 423b to lock the module 430-1 in place. (The mounting features 423, 433 on only one side are visible, but it should be understood that similar mounting features 423, 433 are present on the other side).

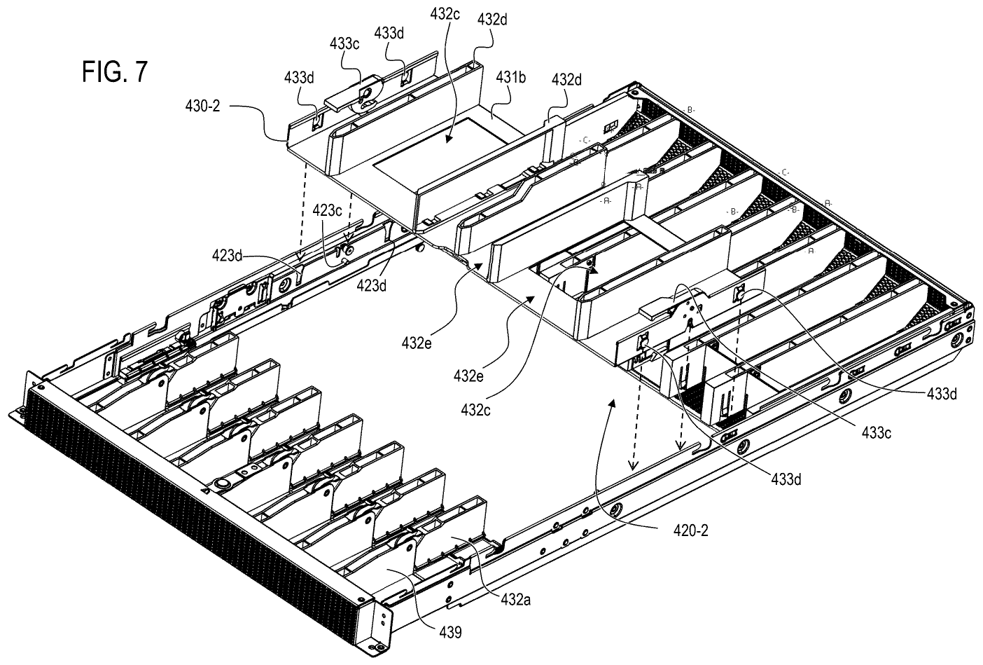

Extension module 430-2 is an example of the first CPU extension module 230-5 and is installed in the CPU module zone 420-2, as shown in FIG. 4. As shown in FIG. 7, the extension module 430-2 includes a tray 431b and multiple guide walls 432d (only some are labeled) coupled perpendicularly to the module tray 431b and disposed parallel to the left and right side walls 411 and 412. The guide walls 432d may define airflow channels 432e (only some labeled) between adjacent guide walls 432d. Some of these airflow channels 432e are wider than others, and in particular two of the wider airflow channels 432e include CPU heatsink cutouts 432c. The CPU heatsink cutouts 432c are positioned over the CPUs 491 of the system 702 when the assembly 400 is installed thereon, as shown in FIG. 10. These cutouts 432c can allow for taller heatsinks 492 to be installed on the CPUs 491, if desired, which can extend upward through the cutouts 432 into the chassis 410 to allow the air passing through some of the airflow channels 432e to pass through the heatsinks 492, as shown by the dash-lined arrows in FIG. 13. Providing this additional airflow through the heatsinks 492 (in addition to the airflow passing through the chassis 480 below the assembly 400) can allow for improved cooling of the CPUs 491. The improved cooling can allow for a reduction in fan speed while still maintaining desired levels of cooling, thus reducing power usage and noise. The use of the larger fans can also contribute to this reduction in power usage and noise, as the larger fans can move more air using less power and at lower rotational speeds than smaller fans.

As shown in FIG. 7, CPU extension zone 420-2 and extension module 430-2 comprise mounting features 423c, 423d and 433c, 433d, respectively, which engage one another to mount the extension module 430-2 to the front module extension zone 420-2. These mounting features can be seen in a disengaged state in FIG. 7 and in an engaged state in FIG. 8. The mounting features 423d comprise slots in the side walls 411 and 412 and the mounting features 433d comprise protrusions which slide into slots of mounting features 423d to support the module 430-2. The mounting features 423c comprise posts coupled to side walls 411 and 412 and the mounting features 433c comprise latches which are actuatable to engage with the posts of mounting features 423b to lock the module 430-2 in place. (The mounting features 423 on only one side are visible, but it should be understood that similar mounting features 423 are present on the other side).

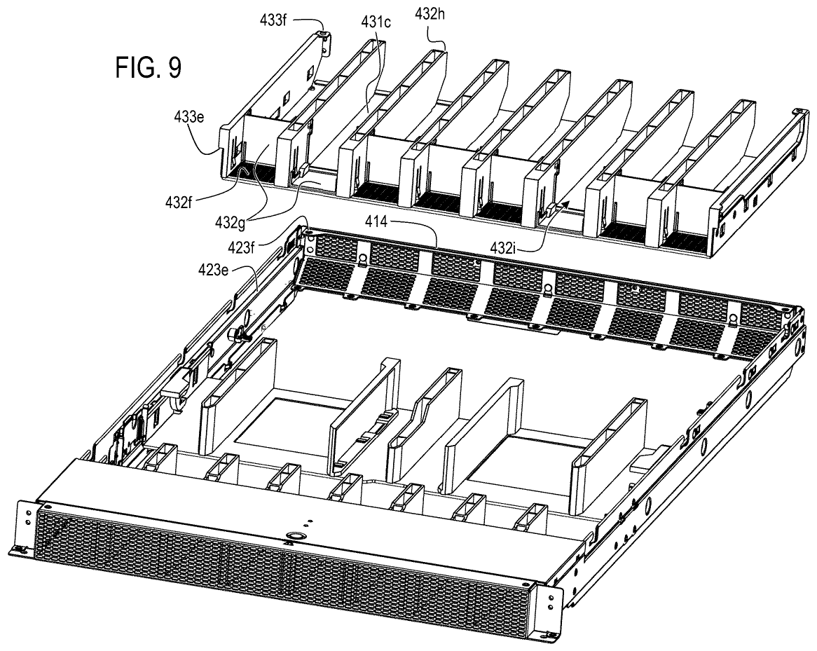

Extension module 430-3 is an example of the first rear extension module 230-7, and is installed in the rear module zone 420-3, as shown in FIG. 4. As shown in FIG. 9, the extension module 430-3 includes a tray 431c and multiple guide walls 432h (only one is labeled) coupled perpendicularly to the module tray 431c and disposed parallel to the left and right side walls 411 and 412. The guide walls 432h may define airflow channels 432i (only one labeled) between adjacent guide walls 432h.

In addition, the rear extension module 430-3 may comprise air doors 432g and diversion apertures 432f (only some labeled). The diversion apertures 432f comprise apertures through the module tray 431, which connect the airflow channels 432i to the space below the module tray 431, i.e., the interior space of the original system chassis. In this example, each set of the diversion apertures 432f is disposed in a corresponding one of the airflow channels 432i. Each airflow door 432g is disposed adjacent to a corresponding set of the diversion apertures 432f. The airflow doors 432g are movable between two configurations-a laid down configuration in which they block airflow through the corresponding set of diversion apertures 432f while allowing airflow through the corresponding airflow channel 432i, and a upright configuration in which they block airflow through the corresponding airflow channel 432i while allowing airflow through the corresponding set of diversion apertures 432f. Thus, first rear extension module 430-7 can provide for variable airflow patterns by adjusting the doors 432g as needed. The airflow doors 432g may be pivotably connected to adjacent guide walls 432h by pivots (not visible) which protrude laterally from a bottom side of the doors 432g and into apertures in the adjacent guide walls 432h.

In some examples, the channels 432i aligned with the CPU openings 432c receive air which has passed through heatsinks 492 and which has therefore been heated. Thus, some or all of the air doors 432g in these channels 432i may be placed in the down position to allow the heated air to be exhausted directly from the system without passing through other components within the chassis 480 This reduces the impedance for these airflow paths (as compared to the airflow paths which flow through the chassis 480), allowing more air to flow through the heatsinks 492 per unit of energy spent driving the fans. This also prevents heated air from being circulated into the system chassis 410, which is beneficial because the heated air is less efficient at cooling the other components in the rear of the system chassis 480. Instead, the components in the rear of the system chassis can receive relatively cool air received from the other airflow channels 432i, which may more efficiently cool those components. The channels 432i which are not aligned with the CPU openings 432c may receive fresh cool airflows which have not been heated by the CPUs 491. Accordingly, the air doors 432g of these channels 432i may be positioned up to redirect these cool airflows back into the system chassis 480 to help further cool devices therein, such as expansion cards 493 at a rear of the system chassis 480 (see FIG. 10). An example of the aforementioned airflow patterns is shown in FIG. 13 by dash-lined arrows.

Note that in some cases, part of the heated air from the heatsink 492 can be directed down into the chassis 480 via an upright door 432g while the other part may be exhausted directly via a laid down door 432g and one of the channels 432i, such as the example illustrate din FIG. 13. In other words, it is not always necessarily that all of the heated air be exhausted directly. In some cases, the increase in airflow provided to the rear of the chassis 480 by flowing some of the heated air there may offset the drop in efficiency due resulting to the air already being heated, resulting in a net increase in efficiency. By providing the doors 432g which are selectively changeable between the upright and lowered positions, a user can tune the airflow as desired to obtain the best results. This allows for more flexibility than a fixed baffle system which may be optimized for one system configuration but which may be poorly suited to another system configuration.

In some cases, the rear module 430-3 at a rear of the assembly 400 may also include devices which need cooling, such as an additional expansion card (not illustrated), in which case the air doors 432g of the channels 432i aligned with this component which needs cooling may be in the down position to ensure that the cooling airflow is delivered thereto. In some examples, a guide wall 432h can be removed to make more room for such a component to be arranged in the rear module 430-3.

In some examples, a rear portion of the module 430-3 may include a cutout (not illustrated) which can allow an expansion card 493 (or other device) in the chassis 480 to extend upward into the assembly 400, allowing for a larger expansion card 493 to be used than would be possible in the chassis 480 alone. In such cases, the air doors 432g of the channels 432i aligned with this expansion card 493 may be in the down position to ensure that the cooling airflow is delivered thereto.

In FIGS. 9-13, the air doors 432g are shown in various arrangements with air some doors 432g down and other up, but it should be understood that the doors 432g could be moved into any desired arrangement and are not limited to the illustrated arrangements. Thus, desired airflow can be tuned by opening/closing the doors 432g.

In other examples, some or all of the doors 432g are not movable between configurations, but instead are fixed in place. For example, some doors 432g may be fixed in the first configuration while others are fixed in the second configuration. In other examples, the diversion apertures 432f and/or air doors 432g may be omitted.

As shown in FIG. 9, rear module extension zone 420-3 and extension module 430-3 comprise mounting features 423e, 423f and 433e, 433f respectively, which engage one another to mount the extension module 430-3 to the front module extension zone 420-3. The mounting features 423e are ledges formed in the side walls 411 and 412, and the mounting features 433e comprise catches protruding from the outermost walls of the tray 431c, which rest on the ledges of mounting features 423e to support the module 430-3. The mounting features 423f comprise apertures through the rear panel 414 of the chassis 410, and the mounting features 433f comprise apertures in the side walls of the tray 431c which align with the mounting features 423f such that a screw or other fastener can be inserted through both mounting features 423f and 433f to lock the module 430-3 in place. (Some of the mounting features 423 are visible on only one side, but it should be understood that similar mounting features 423 are present on the other side).

As shown in FIGS. 6 and 13, the assembly 400 may also comprise fixed front region 438. As shown in FIG. 4, a top panel 419 covers this region 438, but this top panel 419 is omitted from various of the figures to reveal the interior of the front region 438. This front region 438, unlike the extension modules 430, is not removable from the chassis 410 but instead makes up part of the chassis 410. In some examples, this front region 438 includes airflow guides 439. These airflow guides 439 align and engage with the airflow guides 432a of the extension module 430-1 when the module 430-1 is installed in the chassis 410, as shown in FIG. 7. In some examples, the airflow guides 439 are removable, for example to allow for other components to be disposed in the region 438—for example, drive cages for receiving drives could be disposed in this region 438. The front region 438 may be disposed over a drive cage region 489 at a front panel 483 of the system chassis 480, as shown in FIG. 10. This drive cage region 489 may have a top cover which is separate from the cover 486 of the chassis 480 and which remains in place even when the cover 486 is removed. Accordingly, top panel 419 of assembly 400 may also have a similar size and shape as the top panel of the drive cage region 489 so that, when the cover 486 is attached to the assembly, the top panel 419 and the cover 486 collectively cover a top portion of the system, as shown in FIG. 11. In some examples, the top panel 419 may be formed from the top panel of the drive cage region 489—that is, when the assembly 400 is installed on the chassis 480, the top panel of the drive cage region 489 may be removed from the drive cage and installed on top of the chassis 410 as the top panel 419 instead.

In FIGS. 4-13, the various airflow guide features (e.g., 432a, 432d, 432h, and 438) are illustrated as relatively thick structures having two parallel walls and an interior space with ribs/webbing to support the two parallel walls relative to one another. This structure may beneficially allow the modules to be formed from convenient materials (e.g., plastics) through convenient techniques (e.g., injection molding, 3D printing, etc.). However, in other examples the same general structure of the assembly 400 may be used but the structures of the airflow guide features (e.g., 432a, 432d, 432h, and 438) could be modified—for example, thin sheet metal or plastic panels/plates could be used without a hollow interior. Also, the number and arrangements of the airflow guide features (e.g., 432a, 432d, 432h, and 438) is just one example, and more or fewer guide features could be provided.

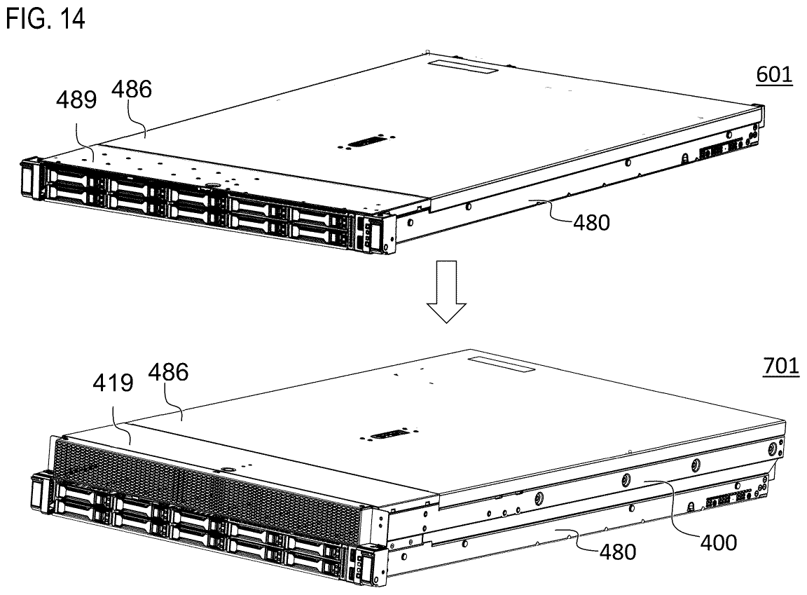

Turning to FIGS. 10-14, the information processing system 701 which has been previously mentioned will be described in greater detail. As shown in FIG. 14, the system 701 is formed by adding the modular extension assembly 400 to a preexisting system 601. In the illustrated example, the system 601 is a 1U server, but it should be understood that this is merely an illustrative example and the assembly 400 could be installed on other systems in a similar manner, including 2U systems, 3U systems, 4U systems, etc. As shown, the addition of the modular extension assembly 400 to the system 601 transforms it into the system 701, which is a 2U system. Thus, the system 701 is larger than the system 601. In other words, adding the assembly 400 to the system 601 increases its size, in particular its height. Similarly, if the assembly 400 were added to a 2U system, it would change it into a 3U system; if added to a 3U system, it would change it to a 4U system, and so on. This increase in size of the system allows for better airflow, as well as providing room for the installation of additional components, if desired, such as larger fans, larger heatsinks, liquid cooling infrastructure, etc. This can allow for better thermals, reduced power consumption, and reduced noise.

As shown in FIG. 10 the systems 701 includes a system chassis 480, a primary system board 490 housed in and supported by the system chassis 480, the modular extension assembly 400 mounted to the system chassis 480, and fans 495 secured to either or both of the system chassis 480 and the assembly 400. The primary system board 490 comprises one or more CPUs 491 mounted thereto (the CPU's are not visible in the figures, as they are covered by CPU heatsinks 492, as shown in FIG. 11). Additional computing components, such as storage drives, memory, expansion cards, and the like may also be included in system 402, as would be familiar to those of ordinary skill in the art. An expansion card 493 is shown in FIG. 10 as one example.

The system chassis 480 comprises a left side wall 481, a right side wall 482, a front panel 483, a rear panel 484, a basepan 485, and a cover 486, which are all connected together to form a box-like structure. The cover 486 may be removable from the rest to allow access to an interior of the system chassis 480. The front panel 483 may include drive bays or other pluggable module bays in which modules may be removably inserted, as well as other apertures to allow airflow. The rear panel 484 may also include various pluggable module bays, apertures to allow airflow, electrical connectors, and the like.

The modular extension assembly 400 is mounted to the system chassis 480 with the extension chassis 410 being coupled thereto. Specifically, the left side wall 411 engages with and extends vertically from the left side wall 481, the right side will 412 engages with and extends vertically from the right side wall 482, the front panel 413 engages with and extends vertically from the front panel 483, and the rear panel 414 engages with and extends vertically from the rear panel 484. Mounting features 415 of the assembly 400 and mounting features 487 of the chassis 480 engage with one another to attach the assembly 400 to the chassis 480 as explained above. Together, the extension chassis 410 and the system chassis 480 for a combined chassis which has dimensions that exceed those of the original system chassis 480, so that the addition of the assembly 410 to the system chassis 480 has expanded the size (volume) of the system.

In this example, the same cover 486 which was designed to be part of the system chassis 480 of system 601 may be mounted to the extension chassis 410 on top of the walls/panels 411, 412, 413, and 414. In particular, mounting features of the cover 486 may engage with the cover mounting features 418 of extension chassis 410, as explained above.

As mentioned previously, the extension modules 430 of the assembly 400 are modifiable or removable and can be replaced by other extension modules, if desired, to allow for customizability of the system 701. For example, one possible modification to the system 701 is to replace the air-cooled heatsinks 492 with a closed loop liquid cooling system. In such a case, space will need to be made for a radiator of the liquid cooling system, and in some cases this space may be found in the front-extension module 430-1. In some examples, the guide walls 432a can be removed from the front extension module 430-1 and the radiator may be disposed on the tray 431a. In other examples, a different extension module (not illustrated) which is designed specifically for the radiator may be disposed in the front zone 420-1 in lieu of the front extension module 430-1. In other examples, a taller (e.g., 2U) radiator may be used and may be installed with a bottom half thereof in the chassis 480 and a top half thereof extending into the assembly 400 in the front module zone 420-1 (in which case, a front module 430 may be omitted). In still other examples, the radiator of the liquid cooling loop could be provided in the CPU zone 420-2 or the rear zone 420-3, or multiple radiators could be distributed throughout multiple of the zones 420-1, 420-2, and 420-3. In some examples in which a liquid cooling loop is added, the CPU extension module 430-2 may be modified to close or cover the CPU openings 432c, as it may no longer be necessary to flow air through any CPU heatsink 492 and having the openings may allow for an undesired bypass route for air.

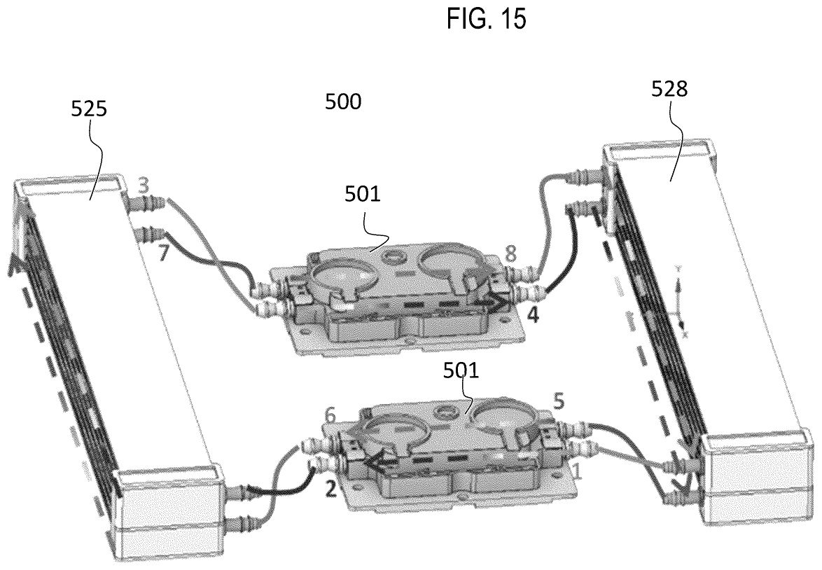

FIG. 15 is a view of an example closed loop liquid cooling system 500 which could be used in a modified version of the system 701. The system 500 comprises two cold plates 501 for mating with CPUs (e.g., the CPUs 491) and front and rear radiators 525/528. When installed, the cold plates 501 may be positioned within the interior of the system chassis 480 disposed on the CPUs 491, with the cold plates being beneath the assembly 400 in alignment with the second extension module zone 420-2. The radiator 525 may be disposed at least partially inside the front module zone 420-1 of the assembly 400. In some examples, it may sit within the front extension modules 430-1 (with guide walls 432 removed) as explained above. In other examples, the radiator may extend through both the chassis 480 and the assembly 400, as mentioned above. The radiator 525, on the other hand, is disposed in the rear module zone 420-3. In some examples, the radiator 525 may sit within the rear extension module 430-3 (with guide walls removed). The cold plates 501 and radiators 525/528 are fluidically connected by tubes/pipes which extend from the system chassis 480 into the assembly 400, for example, via one or more openings in a tray 431 of the middle (CPU) extension module. Fittings and the like may be used to make the fluid connections, as is familiar to those in the art. Pumps may circulate liquid coolant therethrough. The pumps may, for example, be part of the cold plates 501, part of the radiators 525 and/or 528, or provided separately and fluidically coupled to the cold plates 501 or radiators 525/528.

Example modular extension assemblies disclosed herein may not only allow for reconfiguration of or retrofitting of already manufactured systems, but may also be used to manufacture new systems. For example, a 2U system could be manufactured by using a 1U chassis designed for a 1U system together with a modular extension assembly mounted thereto. This may be advantageous as compared to designing separate 1U and 2U chassis because it allows for the re-use of the same part (the 1U chassis) in multiple different systems, which can reduce development and manufacturing costs.

Some chassis extension module could essentially be a 1U “shell” with ventilation holes at the front, allowing for a reduction in airflow impedance through the server. From a 1U perspective, the 1U chassis extension module turns the 1U server into a reduced impedance 2U server. The extra 1U of space gained in the reduced impedance 2U server would allow the size of the processor heatsinks to be increased to match heatsinks developed for 2U servers. The extra space in the reduced impedance 2U server would also allow the 7, 40 mm cooling fans in the 1U server to be replaced with 6, 60 mm cooling fans or 5, 80 mm cooling fans. With lower server impedance, larger cooling fans and larger processor heatsinks, the fan speed of the 60 mm cooling fans (or 80 mm cooling fans) can be lowered compared to the 40 mm cooling fans and still adequately cool the server. Lower fan speed will result in lower power usage compared to the density optimized 1U server. Lower fan speed will also result in a lower acoustical signature for the server. In the case of the 1U server, the fan cage, fan assembly and processor heatsink can be used from our 2U server offerings to reduce tooling expenses and overall 1U chassis extension module costs.

This concept allows manufacturers to continue offering density optimized 1U servers to customers that do not have extra space in their server racks for the 1U chassis extension module. However, with the 1U chassis extension module simply replacing the 1U servers top cover, it could be offered as an option to customers that have empty space in their server racks and want to reduce power usage and the acoustic signature of the servers.

Similarly, the concept could be used for 2U server offerings. In the case of the 2U server, the 1U chassis extension module would turn the 2U server into a reduced impedance 3U server. The 6, 60 mm cooling fans used for cooling the density optimized 2U server would be replaced with 4, 92 mm cooling fans or 3, 120 mm cooling fans. The size of the processor heatsinks for the reduced impedance 3U server could be increased to improve thermal performance of the server. Similar to the reduced impedance 2U server, the reduced impedance 3U server would be more thermally optimized and would result in a reduction in power necessary to cool the server and a lower acoustical signature for the server. The extra space that the 1U chassis extension module offers could also be used to support larger thermal solutions, like liquid cooling solutions, so that more powerful processors could be supported if desired.

The 1U chassis extension module concept is not limited to 1U and 2U servers. The 1U chassis extension module can also be used to convert a 3U server into 4U, 4U into 5U, and so on. Depending on customer environments, the concept could be used across many of product lines in addition to servers, including networking devices, edge devices, or other devices, offering power savings and reduced acoustic signatures for some of our more thermally challenged products. IN addition, modular extension assemblies disclosed herein are not limited to 1U assemblies, but may include any other desired size of an extension assembly, such as a 2U extension assembly (which converts a 1U server into a 3U, converts a 2U server into a 4U, and so on), a 3U extension assembly, or any other size. Moreover, although sizes discussed above are in integer units of “U,” this is merely one example and the size of the underlying system and/or the extension assembly can be any arbitrary size which does not necessarily have to correspond to an integer number of “U”.

In addition, in some circumstances it may be desired to manufacture many different systems having different sizes and configurations utilizing shared components in common.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A modular extension assembly for expanding the size of an information processing system, comprising:
an extension chassis configured to mount to a top of a system chassis of the information processing system;
a fan extension zone comprising an opening arranged to, in an installed state of the extension chassis on the system chassis, receive fans protruding from the system chassis into the extension chassis;
one or more extension module zones in the extension chassis; and
one or more extension modules removably installed in the extension modules zones, respectively,
wherein each extension module comprises a module tray, one or more airflow guides, and a set of mounting features configured to engage with a complimentary set of mounting features in one of the extension module zones to removably couple the respective extension module to the extension module chassis in the respective extension module zone.

2. The assembly of claim 1,
wherein the extension chassis comprises system chassis mounting features configured to engage with first mounting features of the system chassis in the installed state of the modular extension assembly on the system chassis,
wherein the first mounting features are configured to engage with a cover of the system chassis in an uninstalled state of the modular extension assembly on the system chassis.

3. The assembly of claim 2,
wherein the extension chassis comprises cover mounting features configured to engage the cover of the system chassis to mount the cover to a top of the extension chassis in the installed state of the modular extension assembly on the system chassis.

4. The assembly of claim 1,
wherein the fan extension zone is arranged to be located over a fan installation region in the system chassis and to enable fans to be disposed in the fan installation region which exceed the height of the system chassis.

5. The assembly of claim 1,
wherein the extension module zones include a front extension zone forward of the fan extension zone, a central processing unit (CPU) extension zone rearward of the fan extension zone, and a rear extension zone rearward of the CPU extension zone.

6. The assembly of claim 5,
wherein the CPU extension zone comprises CPU openings arranged to be located over CPUs in the system chassis in the installed state of the modular extension assembly on the system chassis.

7. The assembly of claim 6,
wherein CPU openings are configured to receive CPU heatsinks protruding from within the system chassis into the extension chassis in the installed state of the modular extension assembly on the system chassis.

8. The assembly of claim 5,
wherein the rear extension zone comprises a plurality of airflow channels defined between the airflow guides,
wherein the tray of the rear extension zone includes bypass apertures disposed in at least some of the airflow channels,
wherein the rear extension zone comprises actuatable doors disposed in at least some of the airflow channels having the bypass apertures, each door actuatable between a first state in which the respective door blocks the bypass apertures of the respective airflow channel and a second state in which the respective door blocks the respective airflow channel.

9. The assembly of claim 5,
wherein the rear extension zone comprises, or is configured to receive, a radiator of close-loop liquid cooling system.

10. The assembly of claim 5,
wherein the rear extension zone comprises, or is configured to receive, one or more auxiliary fans.

11. The assembly of claim 5,
wherein the rear extension zone comprises, or is configured to receive, an expansion cage configured to house an expansion card.

12. The assembly of claim 11,
wherein the rear extension zone comprises an opening configured to receive the expansion cage extending from the system chassis into the expansion chassis.

13. The assembly of claim 5,
wherein the front extension zone comprises guide walls defining a plurality of airflow channels.

14. The assembly of claim 5,
wherein the front extension zone comprises one or more drive cages configured to removably receive pluggable drives.

15. The assembly of claim 5,
wherein the front extension zone comprises, or is configured to receive, a radiator of close-loop liquid cooling system.

16. The assembly of claim 5,
wherein the front extension zone comprises, or is configured to receive, one or more auxiliary fans.

17. An information processing system, comprising:
a system chassis;
a system board disposed in the system chassis with one or more central processing units (CPUs) mounted to the system board;
a plurality of fans disposed in a fan installation region in the system chassis;
an extension chassis mounted to a top of the system chassis;
a fan extension zone comprising an opening disposed over the fan installation region and receiving part of the fans extending into the extension chassis;
one or more extension module zones in the extension chassis; and
one or more extension modules removably installed in the extension modules zones, respectively,
wherein each extension module comprises a module tray, one or more airflow guides, and a set of mounting features configured to engage with a complimentary set of mounting features in one of the extension module zones to removably couple the respective extension module to the extension module chassis in the respective extension module zone.

18. The information processing system of claim 17,
wherein one of: the system chassis is 1U in height and the information processing system is 2U in height; the system chassis is 2U in height and the information processing system is 3U in height; the system chassis is 3U in height and the information processing system is 4U in height; the system chassis is 4U in height and the information processing system is 5U in height.

19. A method of modifying an information processing system, comprising:
removing a cover of a system chassis of an information processing system comprising a system board disposed in the system chassis with one or more central processing units (CPUs) mounted to the system board;
removing a first set of fans from the system chassis;
installing a second set of fans in the system chassis, the second set of fans having a height exceeding a height of the system chassis;
expanding the size of the information processing system by mounting an extension chassis to a top of the system chassis, the extension chassis comprising:
a fan extension zone comprising an opening arranged to receive part of the second set of fans extending from the system chassis into the extension chassis;
one or more extension module zones in the extension chassis; and
one or more extension modules removably installed in the extension modules zones, respectively, wherein each extension module comprises a module tray and one or more airflow guides; and
mounting the cover to a top of the extension chassis.

20. The method of claim 19:
wherein removing the cover of the system chassis comprises disengaging first mounting features of the cover from second mounting features of the system chassis;
wherein mounting the extension chassis to the system chassis comprises engaging system chassis mounting features of the extension chassis with the second mounting features of the system chassis; and
wherein mounting the cover to the top of the extension chassis comprises engaging the first mounting features of the cover with cover mounting features of the extension chassis.
